(19) United States
(12) Patent Application Publication
(10) Pub. No.: US 2003/0160331 A1
(43) Pub. Date: Aug. 28, 2003

(54) Interconnection structure between wires

(75) Inventor: Masahiko Fujisawa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/214,571

(22) Filed: Aug. 9, 2002

(30) Foreign Application Priority Data
Feb. 22, 2002 (JP) 2002-045917

(51) Int. Cl. H01L 23/48

(52) U.S. Cl. 257/774

(57) ABSTRACT

A recess (20) of an insulation film (1) is filled with a first metal wire (2) with a first conductive barrier layer (3) interposed therebetween. An insulation film (6) is formed on the insulation film (1), the first conductive barrier layer (3) and the first metal wire (2), and a hole (11) reaching the first metal wire (2) is formed in the insulation film (6). Next, a recess (12) communicating with the hole (11) is formed on a surface of the first metal wire (2), following which a second conductive barrier layer (13) is formed on part of a surface (40) of the recess (12), on a surface (41) of the hole (11) and on an upper surface of the insulation film (6) while maintaining the communication between the hole (11) and the recess (12). Next, a second metal wire (14) is provided to fill the recess (12) and the hole (11). Consequently obtained is an interconnection structure in which the first and second metal wires are directly connected to each other at a position.

### BACKGROUND OF THE INVENTION

1. Field of the Invention

The present invention relates to a technique for providing interconnection between wires, e.g., a pair of wires stacked in a thickness direction of a semiconductor device.

2. Description of the Background Art

With advancement in miniaturization of semiconductor integrated circuits, attention has been focused on a wiring delay as a factor of hampering a speedup of device operation. A delay of a semiconductor integrated circuit is the sum of a delay of each transistor serving as a semiconductor element and that of wiring which connects transistors. When various elements constituting a semiconductor device are reduced in size for device miniaturization, the transistor delay is reduced according to the scaling law, whereas the wiring delay increases in proportion to the product of the wiring resistance and wiring capacitance. Thus, a reduction in the wiring resistance reduces the wiring delay, and hence results in a speedup of the semiconductor device.

Accordingly, there is a trend toward the use of copper (Cu) as a wiring material having a resistivity lower than that of an aluminum-based wiring material which has conventionally been used. A wire made of copper (hereinafter referred to as “copper wire”) is also preferable because of its good electromigration resistance as compared to a wire made of an aluminum-based wiring material.

However, copper is characterized by being difficult to be subjected to dry etching as compared to an aluminum-based wiring material. Therefore, to fabricate a copper wire, a method called “buried wiring” is adopted in many cases. With this method, a trench is formed in an insulation film and is filled with metal, following which excess metal is removed by polishing or the like, and metal remaining in the trench is used as a wire.

Copper atoms are also characterized by forming a deep level in a band gap of silicon when entering into silicon. Thus, mixing copper atoms into a MOS transistor constituting an integrated circuit will cause significant deterioration in properties of the MOS transistor. Further, copper atoms diffuse quickly into a silicon oxide film which is generally employed as an insulation film in a semiconductor device. For these reasons, the periphery of a copper wire needs to be covered with a film for preventing the diffusion of copper atoms.

FIG. 16 is a cross-sectional view showing an interconnection structure between wires (hereinafter briefly referred to as “interconnection structure”) according to a first conventional technique. The interconnection structure shown in FIG. 16 includes a pair of copper wires formed by the buried wiring method. In the interconnection structure shown in FIG. 16, an insulation film 101 has a recess 109 having an opening formed on its upper surface side, and a first conductive barrier layer 103 is provided on a surface of the recess 109. A first copper wire 102 is provided to fill the recess 109 with the first conductive barrier layer 103 interposed therebetween. Although not shown in the drawing, there is provided on a lower side of the insulation film 101 (i.e., the opposite side of the recess 109) a semiconductor substrate in which a semiconductor element to be connected to the first copper wire 102 is formed.

A first insulative barrier layer 104 and an interlayer insulation film 105 are stacked in this order on the upper surface of the insulation film 101, an upper end surface of the first conductive barrier layer 103 and an upper surface of the first copper wire 102. The first insulative barrier layer 104 has an opening 110 for exposing part of the upper surface of the first copper wire 102. The interlayer insulation film 105 has a trench 112 having an opening formed on its upper surface side and a connecting hole 111 provided between and communicating with the trench 112 and the opening 110.

A second conductive barrier layer 107 is provided on a surface of the trench 112, a surface of the connecting hole 111, a surface of the opening 110 and an upper surface of the part of the first copper wire 102 exposed by the opening 110. A second copper wire 106 is provided to fill the trench 112, the connecting hole 111 and the opening 110 with the second conductive barrier layer 107 interposed therebetween. Further, a second insulative barrier layer 108 is provided to cover an upper surface of the second copper wire 106, an upper end surface of the second conductive barrier layer 107 and the upper surface of the interlayer insulation film 105.

In the above-described interconnection structure according to the first conventional technique, the first and second copper wires 102 and 106 are adjacent to each other with the second conductive barrier layer 107 interposed therebetween and are electrically connected to each other. These wires 102 and 106 are insulated from each other by the first insulative barrier layer 104 and the interlayer insulation film 105 at a position other than the adjacent position. When a copper wire is formed in the interlayer insulation film 105 in addition to the second copper wire 106, the additional copper wire and the second copper wire 106 are, of course, insulated from each other by the interlayer insulation film 105.

The insulation film 101 and the interlayer insulation film 105 are made of a silicon oxide film, for example. The first insulative barrier layer 104 and the second insulative barrier layer 108 are made of a silicon carbide film or silicon nitride film, for example, in order to provide interlayer insulation while preventing the diffusion of copper atoms into the insulation film 101 and the interlayer insulation film 105. In many cases, the first and second conductive barrier layers 103 and 107 are made of a metallic compound having conductivity for the purpose of reducing the wiring resistance and ensuring an electric connection between the first and second copper wires 102 and 106 while preventing the diffusion of copper atoms from the copper wires into the insulation film 101 or the interlayer insulation film 105.

The above-described interconnection structure of the first conventional technique has the following two disadvantages. First, the presence of the second conductive barrier layer 107 between the wires causes an increase in the connection resistance as compared to the case of directly connecting the wires. A material employed for the second conductive barrier layer 107 generally has a resistivity higher than that of copper. Specifically, copper has a resistivity of approximately 2 μΩcm, whereas tantalum nitride (TaN) and titanium nitride (TiN) which are generally employed for the second conductive barrier layer 107 have resistivities of approximately 220 μΩcm and 200 μΩcm, respectively. In this way, a material employed for the second conductive barrier layer 107 generally has a resistivity higher than that of copper, which causes an increase in the connection resistance between the wires.

The second disadvantage is that a void easily occurs in the first copper wire 102 due to electromigration. Here, “electromigration” represents a phenomenon that a continuous current flow through a wire causes metallic atoms of a metallic material forming the wire to diffuse with an electron stream, so that a void occurs in the wire. As shown in FIG. 17, when an electron flows from the second copper wire 106 to the first copper wire 102, the electron usually changes its moving direction upon entering into the first copper wire 102. This causes an electric field to concentrate in the vicinity of the upper surface of the part of the first copper wire 102 exposed by the opening 110. On the other hand, the presence of the second conductive barrier layer 107 between the first and second copper wires 102 and 106 hardly causes the diffusion of copper atoms of the second copper wire 106 into the first copper wire 102. Thus, as shown in FIG. 18, copper atoms of the first copper wire 102 diffuse with the electron stream, so that a void 120 is likely to occur in a position in the first copper wire 102 under the opening 110.

To solve the above-described second disadvantage, a second conventional technique has been proposed as shown in FIG. 19 in which a third copper wire 130 called “reservoir” connected to the first copper wire 102 is provided on an upstream side of the electron stream in the first copper wire 102. According to this technique, a void is unlikely to occur in the position in the first copper wire 102 under the opening 110 by utilizing the diffusion of copper atoms of the third copper wire 130, as shown in FIG. 20. This allows the conduction between the first and second copper wires 102 and 106 to be maintained for a long period of time as compared to the first conventional technique.

The provision of the third copper wire 130 allows the conduction between the first and second copper wires 102 and 106 to be maintained for long, however, the third copper wire 130 is inherently unnecessary as a wire for connecting elements, which hence becomes a factor of hampering an increase in the density of an integrated circuit. Further, the second conventional technique cannot solve the first disadvantage encountered in the first conventional technique.

### SUMMARY OF THE INVENTION

An object of the present invention is to provide a technique for interconnection between wires that reduces the connection resistance between metal wires and increases reliability of the metal wires.

According to the present invention, an interconnection structure between wires includes a first metal wire having a surface provided with a recess and an insulation film formed on the first metal wire, having therein a hole which communicates with the recess. The interconnection structure further includes a barrier layer formed at least on a surface of the hole and a second metal wire provided on the first metal wire and the barrier layer and directly connected to the first metal wire to fill the hole and the recess.

The first and second metal wires are directly connected to each other, which allows the connection resistance between the wires to be reduced. Further, even if electromigration causes metal atoms of the first metal wire to diffuse, metal atoms are supplied for the first metal wire from the second metal wire, so that a void is unlikely to occur in the first metal wire. This allows the metal wires to have improved reliability.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing an interconnection structure according to a first preferred embodiment of the present invention;

FIGS. 2 to 5 are cross-sectional views showing manufacturing steps of the interconnection structure according to the first preferred embodiment;

FIGS. 6 and 7 are cross-sectional views showing the interconnection structure according to the first preferred embodiment;

FIGS. 8 to 10 are cross-sectional views showing manufacturing steps of the interconnection structure according to the first preferred embodiment;

FIGS. 11 to 13 are cross-sectional views showing manufacturing steps of an interconnection structure according to a third conventional technique;

FIGS. 14 and 15 are cross-sectional views showing manufacturing steps of an interconnection structure according to a second preferred embodiment of the invention;

FIGS. 16 to 18 are cross-sectional views showing an interconnection structure according to a first conventional technique; and

FIGS. 19 and 20 are cross-sectional views showing an interconnection structure according to a second conventional technique.

### DESCRIPTION OF THE PREFERRED EMBODIMENTS

First Preferred Embodiment

FIG. 1 is a cross-sectional view of an interconnection structure according to a first preferred embodiment of the present invention yet to be completed. As shown in FIG. 1, the interconnection structure includes an insulation film 1 having a recess 20 with an opening on its upper surface side, a first conductive barrier layer 3 formed on a surface of the recess 20, a first metal wire 2 having a recess 12 on its surface and an insulation film 6 having therein a hole 11 communicating with the recess 12.

The recess 20 is filled with the first metal wire 2 with the first conductive barrier layer 3 interposed therebetween and has the opening on the upper surface side of the first metal wire 2. The periphery of the recess 12 surrounds that of the hole 11 and has a surface 40 partly present under the insulation film 6.

The insulation film 6 includes a first insulative barrier layer 4 and an interlayer insulation film 5, which are stacked in this order on the upper surface of the insulation film 1, an upper end surface of the first conductive barrier layer 3 and the upper surface of the metal wire 2. The hole 11 extends through the insulation film 6 in its thickness direction to expose the first metal wire 2 and includes a trench 7 and a connecting hole 8 formed in the interlayer insulation film 5 and an opening 9 formed in the first insulative barrier layer 4. The trench 7 has an opening on an upper surface side of the interlayer insulation film 5 and the opening 9 communicates with the recess 12. The connecting hole 8 is provided between and communicates with the trench 7 and the opening 9. Although not shown in the drawing, there is provided on a lower side of the insulation film 1 (i.e., the opposite side of the recess 20) a semiconductor substrate in which a semiconductor element to be connected to the first metal wire 2 is formed.

In the interconnection structure according to the present embodiment configured as above described, forming a second conductive barrier layer on a surface 41 of the hole 11 and part of the surface 40 of the recess 12 while maintaining the communication between the hole 11 and the recess 12 and thereafter forming a second metal wire which fills the hole 11 and the recess 12 provides the interconnection structure in which the first metal wire 2 and the second metal wire are directly connected to each other at a position without the second conductive barrier layer interposed therebetween. Detailed description will be made below.

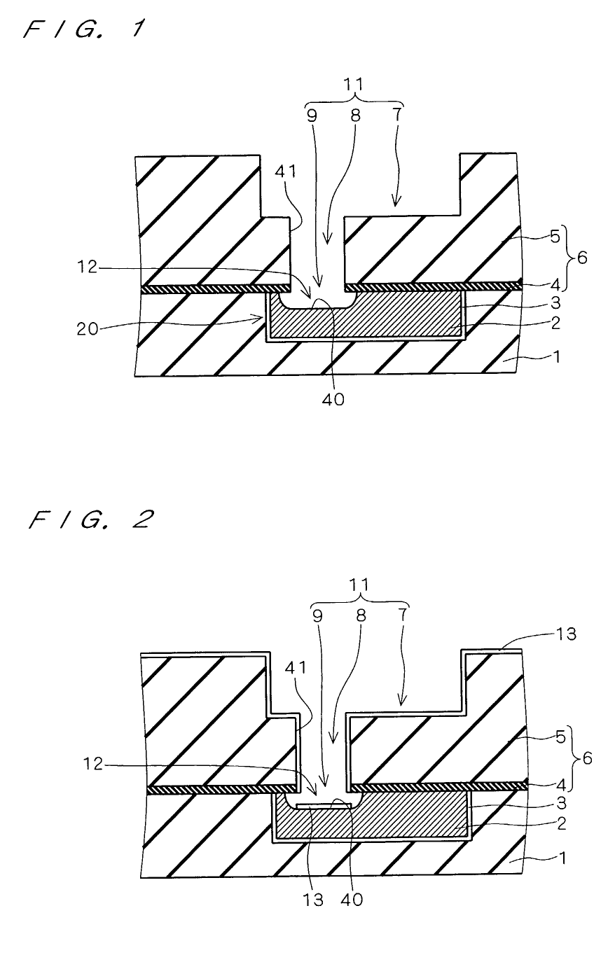

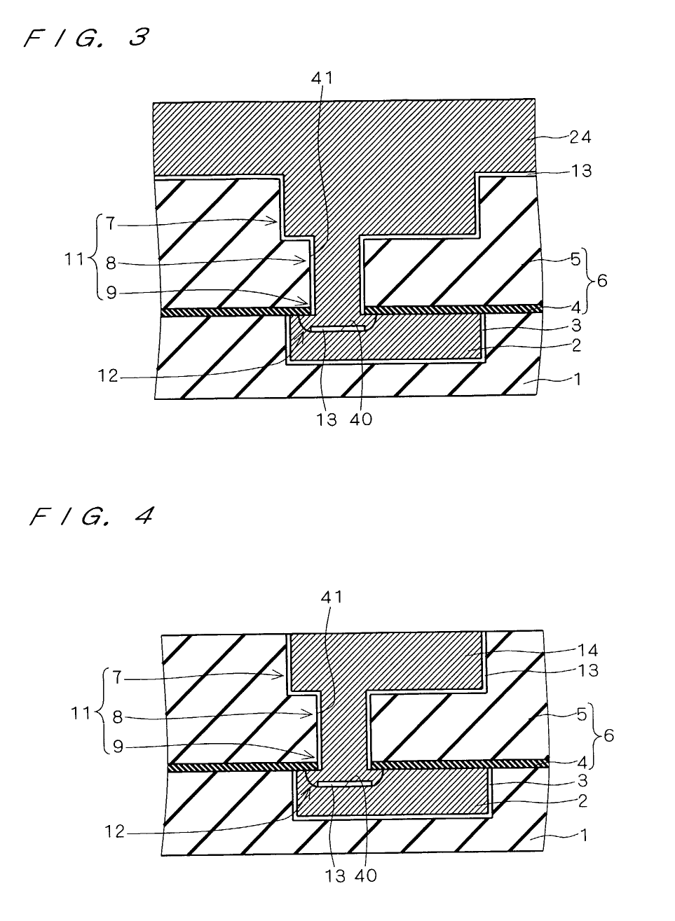

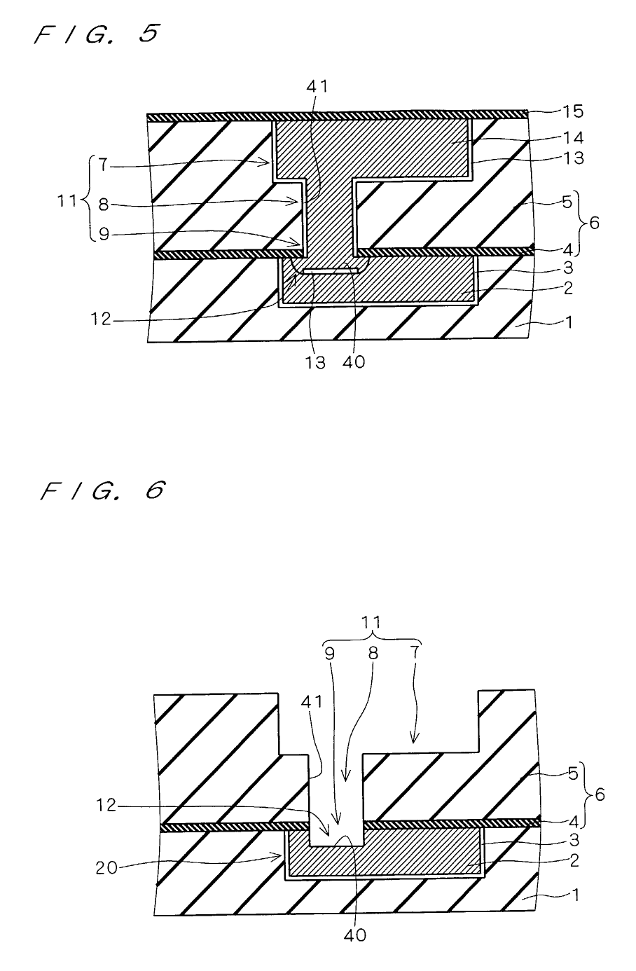

FIGS. 2 to 5 are sectional views showing steps of obtaining the interconnection structure in which the first metal wire 2 and the second metal wire are directly connected to each other at a position from the interconnection structure shown in FIG. 1. Using a physical vapor deposition (PVD) method, for example, a second conductive barrier layer 13 is formed on part of the surface 40 of the recess 12, on the surface 41 of the hole 11 and on an upper surface of the insulation film 6 while maintaining the communication between the hole 11 and the recess 12, as shown in FIG. 2. Next, as shown in FIG. 3, the recess 12 and the hole 11 are filled with a metal film 24 by PVD, chemical vapor deposition (CVD), plating or the like. The metal film 24 is further formed on the upper surface of the insulation film 6 with the second conductive barrier layer 13 interposed therebetween. When the metal film 24 is formed by electroplating, it is preferable to previously form a seed film by CVD with which uniform coverage is obtained in order to improve embedment.

Next, as shown in FIG. 4, the structure obtained in the step shown in FIG. 3 is polished from above using a chemical mechanical polishing (CMP) method to remove part of the metal film 24 and the second conductive barrier layer 13 present above the hole 11. A second metal wire 14 filling the recess 12 and the hole 11 is thereby formed. Next, as shown in FIG. 5, a second insulative barrier layer 15 is formed on an overall surface of the structure obtained in the step shown in FIG. 4, i.e., the upper surface of the insulation film 6, an upper end surface of the second conductive barrier layer 13 and an upper surface of the second metal wire 14, so that the interconnection structure is completed.

As shown in FIG. 5, the completed interconnection structure according to the present embodiment includes the insulation film 1, the first conductive barrier layer 3, the first metal wire 2 having the recess 12 on its surface, the insulation film 6 provided on the first metal wire 2 having therein the hole 11 communicating with the recess 12, the second conductive barrier layer 13 provided on part of the surface 40 of the recess 12 and on the surface 41 of the hole 11, the second metal wire 14 provided on the surfaces of the first metal wire 2 and the second conductive barrier layer 13 and directly connected to the first metal wire 2 to fill the hole 11 and the recess 12, and the second insulative barrier layer 15 provided on the upper surface of the insulation film 6, the upper end surface of the second conductive barrier layer 13 and the upper surface of the second metal wire 14.

The above-described first and second metal wires 2 and 14 are made of a copper wire, for example, and the insulation film 1 and the interlayer insulation film 5 are made of a silicon oxide film, for example. The fist and second insulative barrier layers 4 and 15 are made of a silicon carbide film or silicon nitride film, for example, in order to provide interlayer insulation while preventing the diffusion of copper atoms into the insulation film 1 and the interlayer insulation film 5. The first and second conductive barrier layers 3 and 13 are made of a metallic compound having conductivity for the purpose of reducing wiring resistance and ensuring an electric connection between the first and second metal wires 2 and 14 while preventing the diffusion of metal atoms from the metal wires into the insulation film 1 or the interlayer insulation film 5.

In the interconnection structure according to the present embodiment configured as above described, forming the second conductive barrier layer 13 on the surface 41 of the hole 11 and the part of the surface 40 of the recess 12 while maintaining the communication between the hole 11 and the recess 12 and thereafter forming the second metal wire 14 to fill the hole 11 and the recess 12 provides the interconnection structure in which the first and second metal wires 2 and 14 are directly connected to each other at a position without the second conductive barrier layer 13 interposed therebetween. In such interconnection structure as that shown in FIG. 5, the first metal wire 2 and the second metal wire 14 are directly connected to each other at a position, and the connection resistance between the wires can thus be reduced as compared to the interconnection structures according to the above-described first and second conventional techniques.

Referring back to FIG. 17, even if metal atoms of the first metal wire 2 diffuse due to electromigration when an electron stream flows from the second metal wire 14 to the first metal wire 2, metal atoms are supplied for the first metal wire 2 from the second metal wire 14 through the directly connected position of the first and second metal wires 2 and 14, so that a void is unlikely to occur in the first metal wire 2 where an electric field concentrates. This allows the metal wires to have improved reliability as compared to the aforementioned first conventional technique. As has been described, execution of predetermined steps for the interconnection structure according to the present embodiment shown in FIG. 1 provides the interconnection structure having low connection resistance between the wires and high reliability.

Consideration will now imaginarily be given to a case in which the surface 40 of the recess 12 does not have a portion present under the insulation film 6, i.e., the surface 40 is merely present immediately under the hole 11. Even in this case, if the second conductive barrier layer 13 can be formed on the surface 41 of the hole 11 and the part of the surface 40 of the recess 12 while maintaining the communication between the hole 11 and the recess 12 and the second metal wire 14 can thereafter be formed to fill the hole 11 and the recess 12, the interconnection structure could be obtained in which the first and second metal wires 2 and 14 are directly connected to each other at a position.

However, when PVD which is generally used as a deposition method is employed for forming the second conductive barrier layer 13 in the structure shown in FIG. 6, the second conductive barrier layer 13 is formed entirely on the surface 40 of the recess 12.

On the other hand, the surface 40 of the recess 12 is partly present under the insulation film 6 in the interconnection structure of the present embodiment. Thus, when PVD is used, the second conductive barrier layer 13 is unlikely to be formed at a position under the insulation film 6, but it is mainly formed at a position immediately under the hole 11, i.e., on a bottom of the recess 12, as shown in FIG. 2. Therefore, the second conductive barrier layer 13 in the interconnection structure of the present embodiment can easily be formed by PVD or the like as compared to the interconnection structure in which the surface 40 of the recess 12 does not have a portion present under the insulation film 6. Consequently, the interconnection structure can easily be obtained in which the first metal wire 2 and the second metal wire 14 filling the hole 11 and the recess 12 are directly connected to each other at a position.

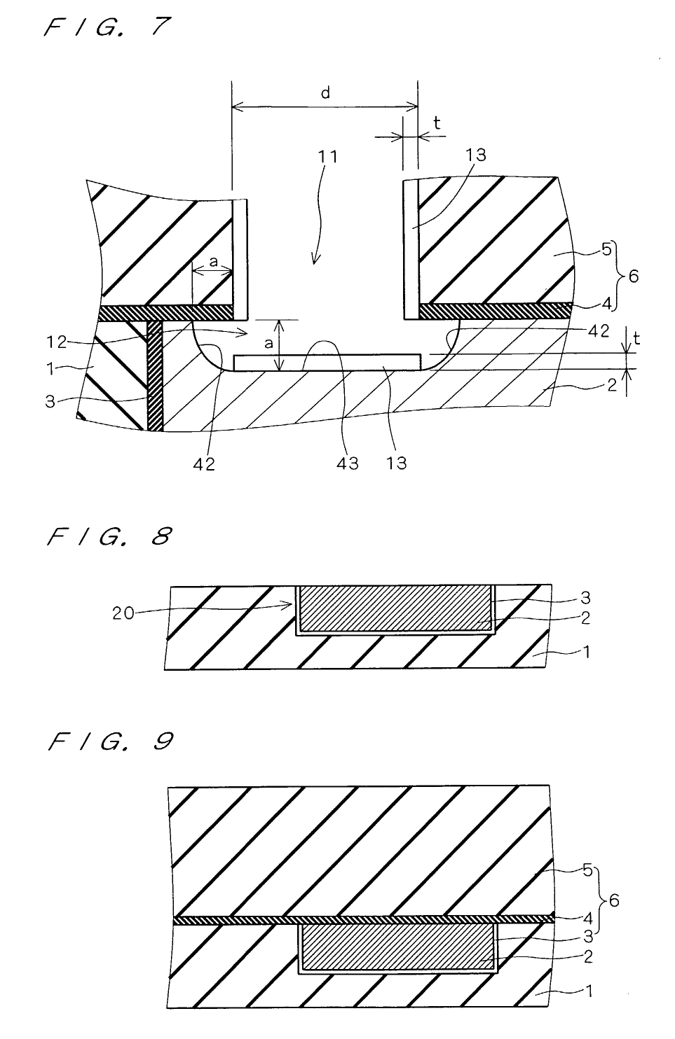

Further, as shown in FIG. 7, it is preferable that a depthwise dimension a of the recess 12 in the interconnection structure of the present embodiment be greater than a film thickness t of the second conductive barrier layer 13 formed on the bottom of the recess 12. If the depthwise dimension a is smaller than the film thickness t of the second conductive barrier layer 13, the second conductive barrier layer 13 formed on the bottom of the recess 12 extends off the recess 12. This makes it difficult to form the second conductive barrier layer 13 with the communication between the hole 11 and the recess 12 being maintained, in other words, without the second conductive barrier layer 13 on the bottom of the recess 12 obstructing the hole 11.

When the depthwise dimension a of the recess 12 is greater than the film thickness t of the second conductive barrier layer 13, however, the second conductive barrier layer 13 can be formed on the bottom of the recess 12 without extending off the recess 12. This makes it easy to form the second conductive barrier layer 13 with the communication between the hole 11 and the recess 12 being maintained as compared to the case where the depthwise dimension a of the recess 12 is smaller than the film thickness t of the second conductive barrier layer 13. Consequently, the interconnection structure can easily be obtained in which the first metal wire 2 and the second metal wire 14 filling the hole 11 and the recess 12 are directly connected to each other at a position.

Next, a method of manufacturing the interconnection structure according to the present embodiment shown in FIG. 1 will be described. FIGS. 8 to 10 are sectional views showing manufacturing steps of the interconnection structure according to the present embodiment. First, as shown in FIG. 8, the recess 20 is formed in the insulation film 1 with an opening on an upper surface side of the insulation film 1, and the first conductive barrier layer 3 is provided on a surface of the recess 20. The first metal wire 2 is provided to fill the recess 20 with the first conductive barrier layer 3 interposed therebetween. To fill the recess 20 with the first metal wire 2, the buried wiring method or patterning using dry etching may be employed. Although not shown in the drawing, there is provided on the lower side of the insulation film 1 (i.e., the opposite side of the recess 20) a semiconductor substrate in which a semiconductor element to be connected to the first metal wire 2 is formed.

Next, as shown in FIG. 9, the insulation film 6 is formed on the upper surface of the insulation film 1, the upper end surface of the first conductive barrier layer 3 and the upper surface of the first metal wire 2. Specifically, the first insulative barrier layer 4 and the interlayer insulation film 5 constituting the insulation film 6 are stacked in this order on the upper surface of the insulation film 1, the upper end surface of the first conductive barrier layer 3 and the upper surface of the first metal wire 2.

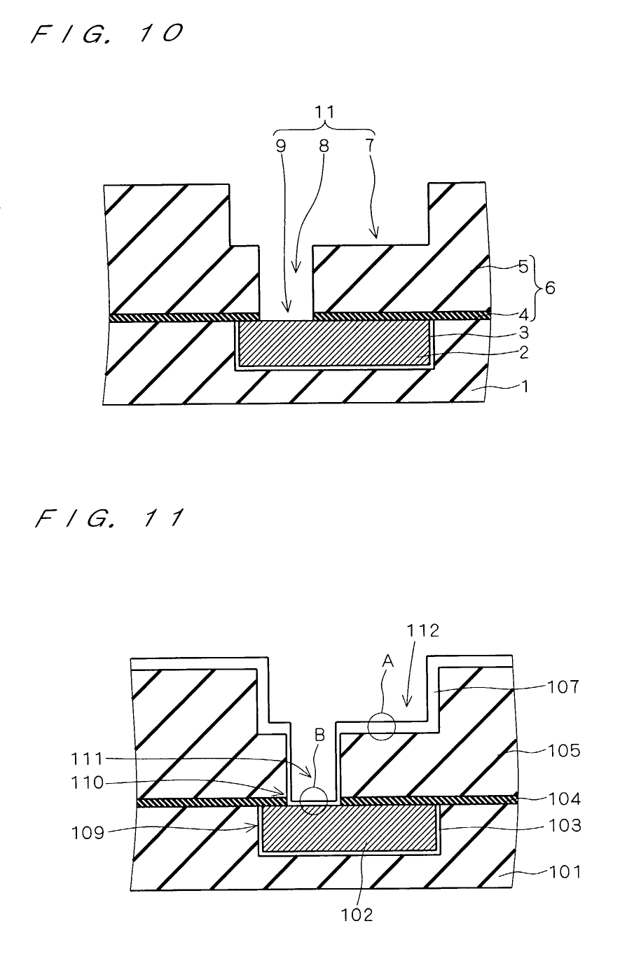

As shown in FIG. 10, the hole 11 reaching the first metal wire 2 is formed in the insulation film 6 by dry etching. Specifically, formed in the interlayer insulation film 5 are the trench 7 having an opening on the upper surface side of the interlayer insulation film 5 and the connecting hole 8 communicating with the trench 7, and formed in the first insulative barrier layer 4 is the opening 9 communicating with the connecting hole 8 to reach the first metal wire 2. Thus, the hole 11 is obtained which extends through the insulation film 6 in its thickness direction to expose the first metal wire 2.

Subsequently, isotropic etching is performed for the first metal wire 2 exposed by execution of the step shown in FIG. 10 to form the recess 12 communicating with the hole 11 in the surface of the first metal wire 2, so that the structure shown in FIG. 1 is obtained. Isotropic etching performed here may be wet etching using nitric acid which dissolves copper or dry etching by means of reactive ion etching using gas which includes chlorine. When nitric acid diluted at the rate of 100:1 is used at room temperature to form the recess 12, an etching process may be performed for 100 seconds in order to set the depthwise dimension of the recess 12 to 100 nm, for example, as copper has an etch rate of approximately 60 nm/min. In other words, the depthwise dimension of the recess 12 is adjustable by adjusting etching process time.

FIGS. 1 to 5 and 8 to 10 as mentioned above show a series of manufacturing steps of the interconnection structure in which the first and second metal wires 2 and 14 are directly connected to each other at a position without the second conductive barrier layer 13 interposed therebetween. Taking the aforementioned description of the first preferred embodiment as being directed to the method of manufacturing the interconnection structure according to the present embodiment, the following can be said. That is, with the method of the present embodiment, the surface 40 of the recess 12 has a portion where the second conductive barrier layer 13 is not formed, and the second metal wire 14 is formed to fill the hole 11 and the recess 12 while maintaining the communication between the hole 11 and the recess 12. Therefore, after forming the second metal wire 14, the first and second metal wires 2 and 14 are directly connected to each other at a position without the second conductive barrier layer 13 interposed therebetween. Thus, even if metal atoms of the first metal wire 2 diffuse due to electromigration when an electron stream flows from the second metal wire 14 into the first metal wire 2, metal atoms are supplied for the first metal wire 2 from the second metal wire 14, so that a void is unlikely to occur in the first metal wire 2 where an electric field concentrates. This allows the interconnection structure to have metal wires with improved reliability as compared to the first conventional technique.

Further, the presence of the position where the first and second metal wires 2 and 14 are directly connected allows the connection resistance between the wires to be reduced as compared to the interconnection structures of the first and second conventional techniques. On the other hand, the second conductive barrier layer 13 formed on the surface 41 of the hole 11 prevents the diffusion of metal atoms from the second metal wire 14 into the insulation film 6.

With the method of manufacturing the interconnection structure of the present embodiment, the second conductive barrier layer 13 is formed partly on the surface 40 of the recess 12 by PVD. With the conventional CVD method, which makes it difficult to form the second conductive barrier layer 13 partly on the surface 40 of the recess 12, the second conductive barrier layer 13 is formed on the overall surface of the surface 40 of the recess 12. With the PVD method, however, the second conductive barrier layer 13 is unlikely to be formed at a position of the surface 40 of the recess 12 present under the insulation film 6, but it is mainly formed at the position present under the hole 11. Thus, the second conductive barrier layer 13 can easily be formed partly on the surface 40 of the recess 12 as compared to the case of using the CVD method.

Further, the method of the present embodiment eliminates the necessity to provide a metal wire merely for reducing the occurrence of a void different from the second conventional technique. Thus, the method of the present embodiment does not hamper an increase in the density of an integrated circuit.

When taking the description of the present embodiment as being directed to the method of manufacturing the interconnection structure, since the surface 40 of the recess 12 is partly present under the insulation film 6, the second conductive barrier layer 13 can easily be formed partly on the surface 40 of the recess 12 as compared to the case in which the surface 40 does not include a portion present under the insulation film 6.

As has been described, the two disadvantages encountered in the first conventional technique can be solved by the interconnection structure of the present embodiment. On the other hand, a third conventional technique has been proposed for solving the two disadvantages in the first conventional technique by another manufacturing method different from that of the present embodiment.

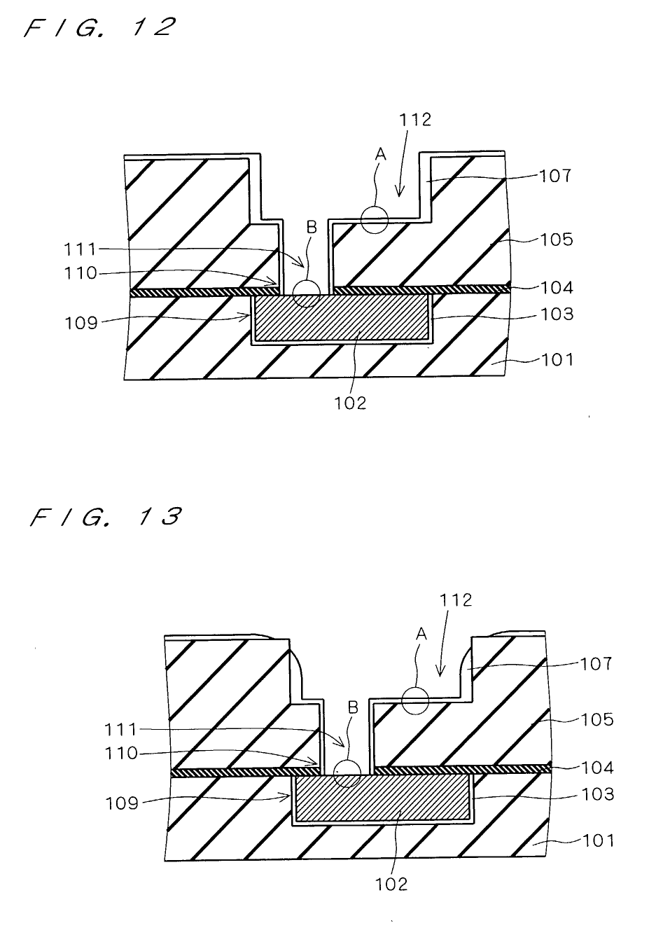

The third conventional technique provides an interconnection structure in which a second conductive barrier layer 107 formed on an upper surface of a first copper wire 102 exposed at an opening 110 is removed, thereby providing a direct connection between the first copper wire 102 and a second copper wire 106. FIGS. 11 and 12 are cross-sectional views showing manufacturing steps of the interconnection structure according to the third conventional technique. A portion denoted by A in these drawings is part of the second conductive barrier layer 107 formed on a bottom of a trench 112, and a portion denoted by B is part of the second conductive barrier layer 107 formed on the upper surface of the first copper wire 102 exposed at the opening 110.

As indicated by the portions A and B, the second conductive barrier layer 107 is formed such that its thickness on the upper surface of the first copper wire 102 exposed at the opening 110 is thinner than that on the bottom of the trench 112. Next, as shown in FIG. 12, the overall surface of the structure shown in FIG. 11 is subjected to anisotropic etching to remove the second conductive barrier layer 107 on the upper surface of the first copper wire 102 exposed at the opening 110 while leaving the second conductive barrier layer 107 on the bottom of the trench 112. As described, by removing the second conductive barrier layer 107 on the upper surface of the first copper wire 102, the interconnection structure can be obtained in which the first copper wire 102 and the second copper wire 106 (not shown in FIG. 12) filling the trench 112, the connecting hole 111 and the opening 110 are directly connected to each other.

In the third conventional technique, the direct connection between the first and second copper wires 102 and 106 reduces the connection resistance between the wires. Further, when there occurs an electron stream flowing from the second copper wire 106 to the first copper wire 102, copper atoms of the second copper wire 106 diffuse into the first copper wire 102, so that a void is unlikely to occur in the first copper wire 102.

However, the third conventional technique has a disadvantage in that a minute interconnection structure requires the second conductive barrier layer 107 to be extremely thick in order to leave the second conductive barrier layer 107 on the bottom of the trench 112, which causes a decrease in the volume of the second copper wire 106 filling the trench 112 and an increase in the wiring resistance.

Anisotropic etching is known to have a property that an etch rate in a recess of a minute pattern is less than that in a flat portion. This phenomenon is called “RIE lag”. The RIE lag causes a decrease in the etch rate on the second conductive barrier layer 107 on the upper surface of the first copper wire 102 exposed at the opening 110 as compared to that on the second conductive barrier layer 107 on the bottom of the trench 112. This requires that the second conductive barrier layer 107 on the bottom of the trench 112 be extremely thick in order to remove the second conductive barrier layer 107 on the upper surface of the first copper wire 102 exposed at the opening 110 and to leave the second conductive barrier layer 107 on the bottom of the trench 112. As a result, the wiring resistance of the second copper wire 106 increases. Since this disadvantage becomes more significant with size reduction of wires, the third conventional technique is becoming unsuitable with recent advancement in miniaturization of semiconductor devices.

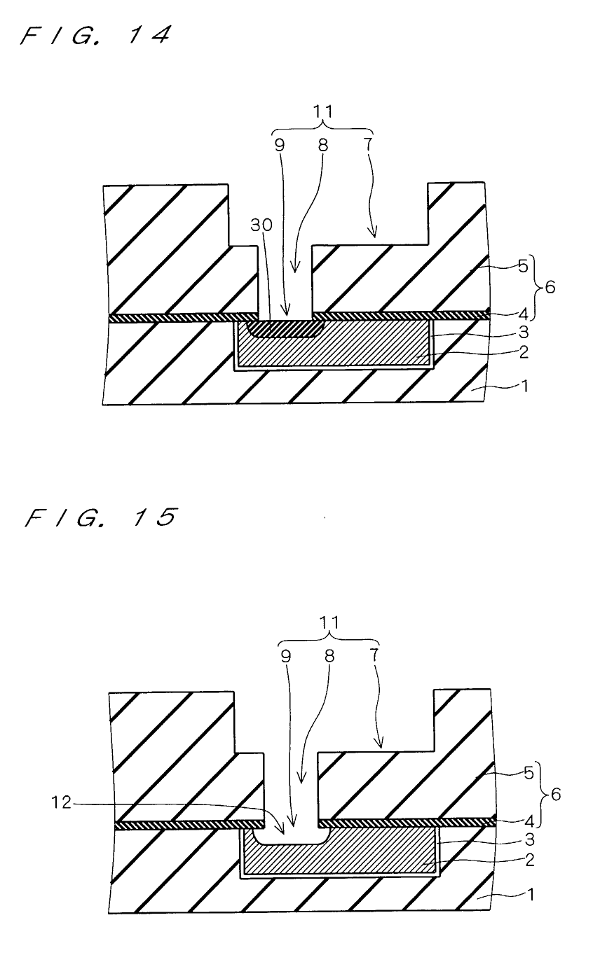

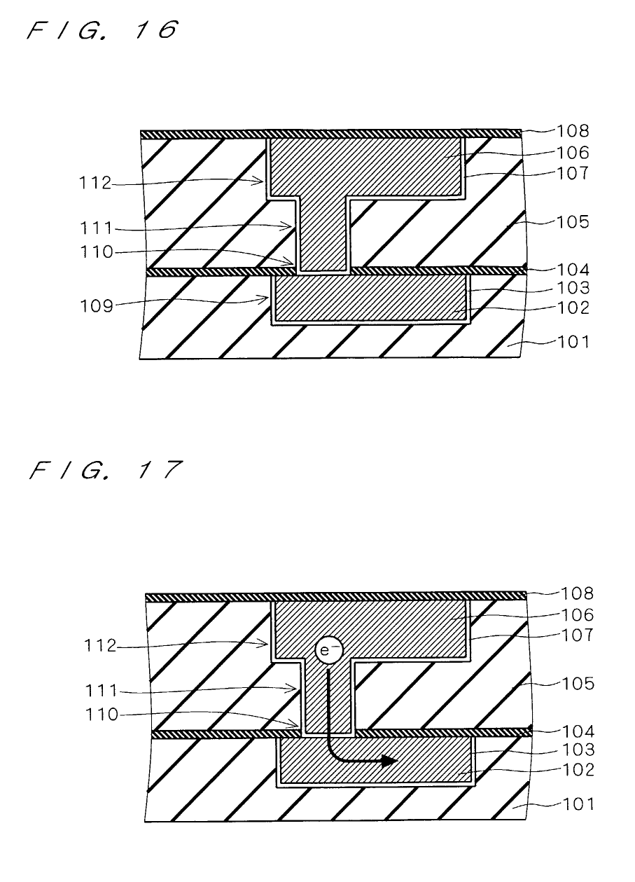

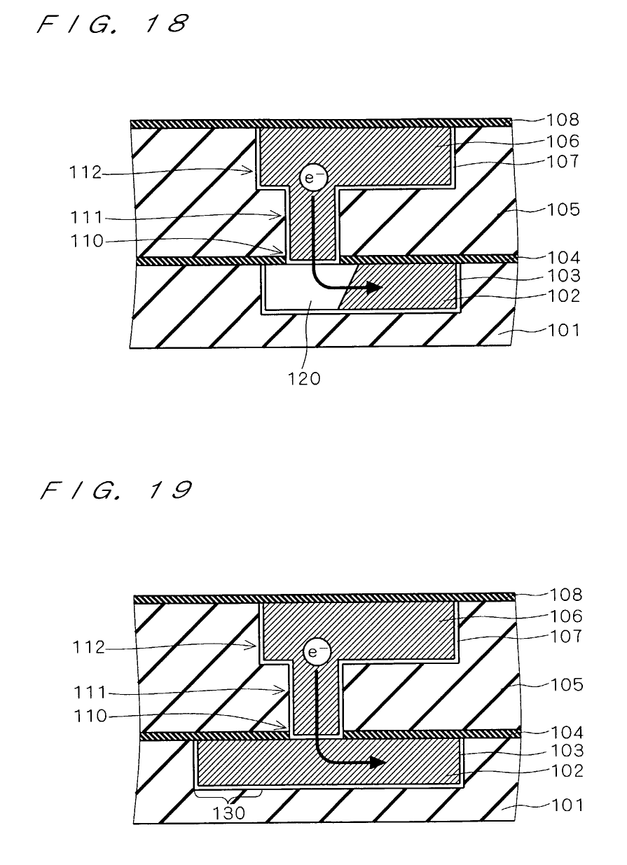

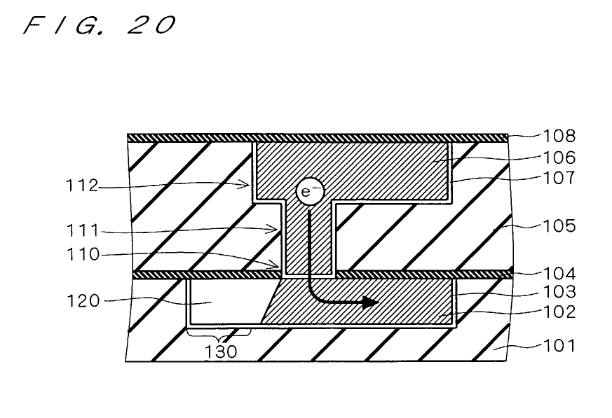

Anisotropic etching has another property that the etch rate generally becomes extremely great at a corner of a projection-like structure. This arises a problem in that, as shown in FIG. 13, when subjected to anisotropic etching, the second conductive barrier layer 107 formed on the surface of the trench 112 is partly removed, following which copper atoms of the second copper wire 106 provided thereafter to fill the trench 112 diffuse into the interlayer insulation film 105, resulting in occurrence of a defective semiconductor element.

Further, taking a variation in the etching amount in anisotropic etching within a wafer and the stability between wafers into consideration, it has been difficult to leave the second conductive barrier layer 107 stably on the bottom of the trench 112.

With the method of the present embodiment, since the second conductive barrier layer 13 is formed by PVD, for example, it is not necessary to etch the second conductive barrier layer 13, different from the third conventional technique. Thus, the second conductive barrier layer 13 on the bottom of the trench 7 does not need to be extremely thick and the second conductive barrier layer 13 formed on the surface of the trench 7 is not partly removed, different from the third conventional technique. As a result, the above-described disadvantage encountered in the third conventional technique does not occur, which allows the interconnection structure to have high reliability. The third conventional technique is disclosed in Japanese Patent Application Laid-Open No. 9-326433, for example.

When taking the description of the present embodiment as being directed to the method of manufacturing the interconnection structure, it is also preferable as shown in FIG. 7 that the depthwise dimension a of the recess 12 be greater than the film thickness t of the second conductive barrier layer 13 formed on the bottom of the recess 12. In this case, it is easy to form the second conductive barrier layer 13 while maintaining the communication between the hole 11 and the recess 12 as compared to the case in which the depthwise dimension a is smaller than the film thickness t.

In view of reduction of the wiring resistance between wires, it is preferable that the dimension a and the diameter d of the hole 11 satisfy the following expression (1). Specifically, the diameter d of the hole 11 is the diameter of the opening 9 among components of the hole 11 which directly communicates with the recess 12.

2πa/4≧d/2 (1)

When isotropic etching is adopted to form the recess 12 as in the first embodiment, etching of the first metal wire 2 proceeds both in the vertical and horizontal directions. Thus, as shown in FIG. 7, an edge 42 of the recess 12 has a shape of quarter circle whose radius is the depthwise dimension a of the recess 12. Therefore, the edge 42 has a length of 2πa/4 in cross section. That is, the left term of the expression (1) represents the length of the edge 42 in cross section. A bottom 43 as part of the recess 12 arranged parallel to the upper surface of the first metal wire 2 where the recess 12 is not formed has a length in cross section equal to the diameter d of the hole 11. That is, the right term of the expression (1) represents half of the length of the bottom 43 in cross section.

When the recess 12 is formed by isotropic etching, the bottom 43 of the recess 12 is positioned immediately under the hole 11 and the edge 42 of the recess 12 is positioned under the insulation film 6. Thus, using PVD, for example, the second conductive barrier layer 13 is formed on the bottom 43 of the recess 12 but it is less likely to be formed on the edge 42 of the recess 12. Therefore, the first metal wire 2 and the second metal wire 14 filing the hole 11 and the recess 12 are directly connected to each other at the edge 42 of the recess 12, while these wires 2 and 14 are connected to each other with the second conductive barrier layer 13 interposed therebetween at the bottom 43 of the recess 12.

Accordingly, in view of reduction of the wiring resistance between wires, it is preferable that the edge 42 of the recess 12 be larger in area to the utmost than the bottom 43. Thus, the above expression (1) was obtained experimentally for reducing the wiring resistance between wires.

Second Preferred Embodiment

FIGS. 14 and 15 are cross-sectional views showing manufacturing steps of an interconnection structure according to a second preferred embodiment. A method of manufacturing the interconnection structure of the present embodiment is different from that of the first preferred embodiment in the method of forming the recess 12. The method of forming the recess 12 will mainly be described in the present embodiment.

First, the steps shown in FIGS. 8 to 10 are executed to form the hole 11 extending through the insulation film 6 in its thickness direction to expose the first metal wire 2. Next, as shown in FIG. 14, the first metal wire 2 exposed by the step shown in FIG. 10 is oxidized at its surface. Specifically, the structure shown in FIG. 10 is subjected to heat treatment under oxidizing environment or subjected to an oxygen plasma process, so that the exposed surface of the first metal wire 2 is oxidized. Heat treatment under oxidizing environment is performed at 120° C. for 30 minutes, for example.

Next, as shown in FIG. 15, a portion 30 oxidized by the step shown in FIG. 14 (hereinafter referred to as “oxidized portion 30”) is removed to form the recess 12. Specifically, a wet process is performed using a chemical solution such as hydrofluoric acid or hydrochloric acid which dissolves copper oxide without dissolving copper. With such wet process, the oxidized portion 30 is removed while the first metal wire 2 is not subjected to etching.

The above-described oxidization performed for the exposed surface of the first metal wire 2 proceeds isotropically. Thus, the removal of the oxidized portion 30 allows a recess of the same shape as the recess 12 shown in the first preferred embodiment to be formed in the surface of the first metal wire 2.

Execution of the steps shown in FIGS. 2 to 5 provides the interconnection structure in which the first metal wire 2 and the second metal wire 14 are directly connected to each other at a position.

In the present embodiment, the first metal wire 2 is oxidized and the oxidized portion is removed, thereby forming the recess 12. Therefore, the shape of the recess 12 is adjusted by controlling the amount of oxidation. Generally, the amount of oxidation is easy to control as compared to the amount of etching. Thus, the shape of the recess 12 is easily adjusted with the method of the present embodiment as compared to the case of forming the recess 12 by isotropic etching as in the first preferred embodiment. Consequently, the recess 12 can easily be adjusted to a desired shape as compared to the method of the first preferred embodiment.

The recess 12 is formed by one step in the method of the first preferred embodiment, whereas the method of the present embodiment requires two steps of oxidizing and removing the oxidized portion. Thus, the first preferred embodiment requires less number of steps to form the recess 12 as compared to the second preferred embodiment in terms of the number of steps.

While the invention has been shown and described in detail, the foregoing description is in all aspects illustrative and not restrictive. It is therefore understood that numerous modifications and variations can be devised without departing from the scope of the invention.

What is claimed is:

1. An interconnection structure between wires comprising:
a first metal wire having a surface provided with a recess;
an insulation film formed on said first metal wire, having therein a hole which communicates with said recess;
a barrier layer formed at least on a surface of said hole; and
a second metal wire provided on said first metal wire and said barrier layer and directly connected to said first metal wire to fill said hole and said recess.

2. The structure according to claim 1, wherein
said barrier layer is also formed on a bottom of said recess, and
said recess has a depthwise dimension greater than a film thickness of said barrier layer.

3. The structure according to claim 1, wherein
said hole extends through said insulation film in a film thickness direction thereof to expose said first metal wire, and
a surface of said recess is partly positioned under said insulation film.

4. The structure according to claim 2, wherein
said hole extends through said insulation film in a film thickness direction thereof to expose said first metal wire, and
a surface of said recess is partly positioned under said insulation film.

5. The structure according to claim 1, wherein
said first and second metal wires are made of copper.
